(19) United States
(12) Patent Application Publication
(10) Pub. No.: US 2025/0239742 A1
(43) Pub. Date: Jul. 24, 2025

(54) POWER MODULE, OUTER WALL RESIN FOR POWER MODULE, AND METHOD OF MANUFACTURING POWER MODULE

(71) Applicant: Asahi Kasei Microdevices Corporation, Tokyo (JP)

(72) Inventor: Kenji KURIYAMA, Tokyo (JP)

(21) Appl. No.: 19/023,401

(22) Filed: Jan. 16, 2025

(30) Foreign Application Priority Data
Jan. 19, 2024 (JP) 2024-007063
Nov. 5, 2024 (JP) 2024-193713

(51) Int. Cl. H01M 50/507; H01M 10/48; H01M 50/505; H01M 50/524

(52) U.S. Cl. CPC H01M 50/507; H01M 10/48; H01M 50/505; H01M 50/524

(57) ABSTRACT

A power module has a bus bar, a magnetic detection unit, and outer wall resin, in which the outer wall resin has an insertion hole into which the magnetic detection unit is inserted, and when seen from an insertion direction of the magnetic detection unit, the insertion hole has a shape corresponding to an outer shape of the magnetic detection unit. There is provided a method of manufacturing a power module which has a bus bar and a magnetic detection unit, the method of manufacturing a power module including: performing resin molding on the bus bar, and forming outer wall resin having an insertion hole into which the magnetic detection unit is inserted; and inserting the magnetic detection unit into the insertion hole.

The contents of the following patent application(s) are incorporated herein by reference:
NO. 2024-007063 filed in JP on Jan. 19, 2024
NO. 2024-193713 filed in JP on Nov. 5, 2024.

### BACKGROUND

### 1. Technical Field

The present invention relates to a power module, outer wall resin for a power module, and a method of manufacturing a power module.

### 2. Related Art

Patent Document 1 discloses an “electrical device capable of simplifying and downsizing a configuration of the electrical device and further contributing to shielding effects”. Patent Document 2 discloses a “power module provided with a sensing unit”.

### PRIOR ART DOCUMENTS

### Patent Document

Patent Document 1: Japanese Patent Application Publication No. 2023-138260
Patent Document 2: Specification of U.S. Patent Application Publication No.

2022/0262773

### BRIEF DESCRIPTION OF THE DRAWINGS

FIG. 1 is a perspective view showing an example of a schematic configuration of a power module 101 in a first embodiment.

FIG. 2 is a perspective view showing an example of a schematic configuration of a bus bar 20 in first, second, third and fourth embodiments.

FIG. 3 is a perspective view showing an example of a schematic configuration of a magnetic detection unit 30 in the first embodiment.

FIG. 4 is an exploded perspective view showing an example of a schematic configuration of the power module 101 in the first embodiment.

FIG. 5 is a first example of a top plan view showing a schematic configuration of an insertion hole 11 in the first embodiment.

FIG. 6 is a first example of a side cross sectional view showing a schematic configuration of the insertion hole 11 in the first embodiment.

FIG. 7 is a second example of a side cross sectional view showing a schematic configuration of the insertion hole 11 in the first embodiment.

FIG. 8 is a perspective view showing an example of a schematic configuration of a power module 102 in the second embodiment.

FIG. 9 is a perspective view showing an example of a schematic configuration of a magnetic detection unit 30a in the second embodiment.

FIG. 10 is an exploded perspective view showing an example of a schematic configuration of the power module 102 in the second embodiment.

FIG. 11 is a top plan view showing a schematic configuration of the insertion hole 11 in the second embodiment.

FIG. 12 is a side cross sectional view showing a schematic configuration of the insertion hole 11 in the second embodiment.

FIG. 13 is a perspective view showing an example of a schematic configuration of a power module 103 in the third embodiment.

FIG. 14 is a perspective view showing an example of a schematic configuration of a power module 104 in the fourth embodiment.

FIG. 15 is a perspective view showing an example of a schematic configuration of a power module 105 in a fifth embodiment.

FIG. 16 is a side cross sectional view showing a schematic configuration of the power module 105 in the fifth embodiment.

FIG. 17 is another example of the side cross sectional view showing a schematic configuration of the power module 105 in the fifth embodiment.

FIG. 18 is a perspective view showing an example of a schematic configuration of a power module 106 in a sixth embodiment.

FIG. 19 is a side cross sectional view showing a schematic configuration of the power module 106 in the sixth embodiment.

FIG. 20 is another example of the side cross sectional view showing a schematic configuration of the power module 106 in the sixth embodiment.

FIG. 21 is a perspective view showing an example of a schematic configuration of a power module 107 in a seventh embodiment.

FIG. 22 is a perspective view showing an example of a schematic configuration of a power module 108 in an eighth embodiment.

FIG. 23 is an illustration showing a part of a process of manufacturing the power module 101 in the first embodiment.

FIG. 24 is an illustration showing a part of the process of manufacturing the power module 101 in the first embodiment.

FIG. 25 is an illustration showing a part of the process of manufacturing the power module 101 in the first embodiment.

FIG. 26 is an illustration showing a part of a process of manufacturing the power module 102 in the second embodiment.

FIG. 27 is an illustration showing a part of the process of manufacturing the power module 102 in the second embodiment.

FIG. 28 is an illustration showing a part of the process of manufacturing the power module 102 in the second embodiment.

FIG. 29 is a perspective view showing an example of a schematic configuration of a modified example of the bus bar 20.

FIG. 30 is a perspective view showing an example of a schematic configuration of a modified example of the bus bar 20.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

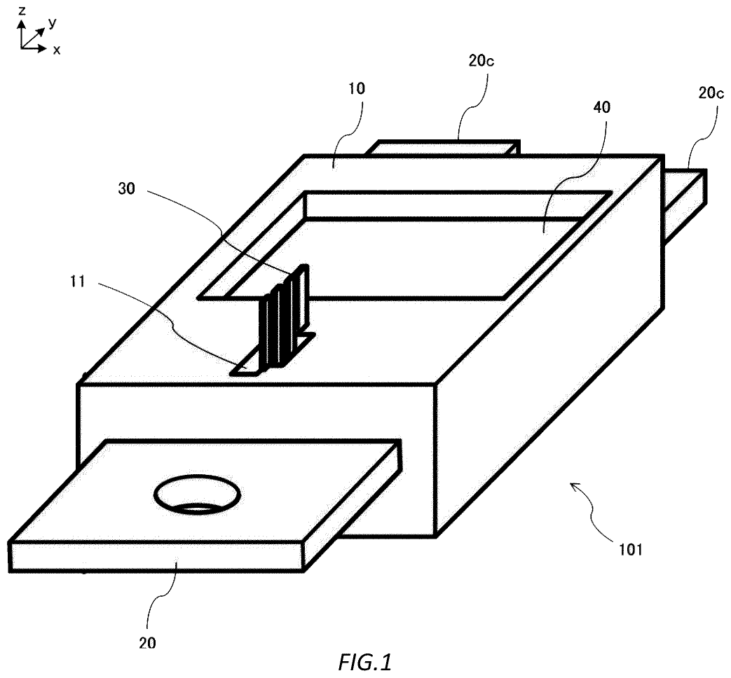

FIG. 1 is a perspective view showing an example of a schematic configuration of a power module 101 in a first embodiment. In each figure, the xyz coordinate system is shown. As shown in FIG. 1, the power module 101 has outer wall resin 10, a bus bar 20 protruding in a −y direction, a magnetic detection unit 30, protective resin 40, and two other bus bars 20c protruding in a +y direction. The power module 101 in the first embodiment is a single phase power module. The outer wall resin 10 forms an outer wall of the power module 101 and is formed to cover the power module 101. It should be noted that the bus bar 20 is a conductor and is used for an inflow and an outflow of a current from an outside, and is also used as a conductor for measuring the current. That is, when the bus bar 20 is incorporated into the power module 101, the bus bar 20 may be a conductor through which the current to be measured flows. In addition, the bus bar 20c is used as a conductor to be connected to a battery. The protective resin 40 is provided to protect each component inside the power module 101. As the protective resin 40, gel-like resin such as silicone resin, or epoxy resin is used.

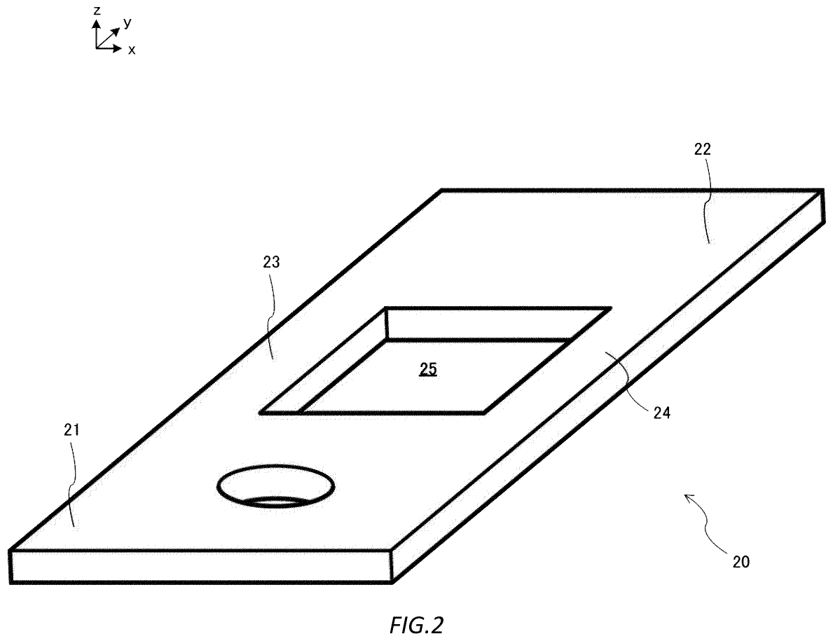

FIG. 2 is a perspective view showing an example of a schematic configuration of the bus bar 20 in the first embodiment. The bus bar 20 has two main body portions 21, 22, two current paths 23, 24, and a through hole 25. It should be noted that the bus bar 20 shown in FIG. 2 is also used in second, third and fourth embodiments.

As shown in FIG. 2, the two main body portions 21, 22 are arranged side by side in a y direction. The two current paths 23, 24 are arranged between the two main body portions 21, 22 and extend parallel to each other, and connect the two main body portions 21, 22. The through hole 25 is arranged between the two current paths 23, 24. The current to be measured flows through each of the two current paths 23, 24 in the same direction. In the present embodiment, the two current paths 23, 24 are conductors having a rectangular transverse cross sectional shape and extending linearly. It should be noted that the transverse cross sectional shape of the two current paths 23, 24 may be any shape such as a circle or an ellipse. Similarly, the shape of the main body portion 22 is rectangular in the figure, but may be freely changed depending on a structure of the power module 101.

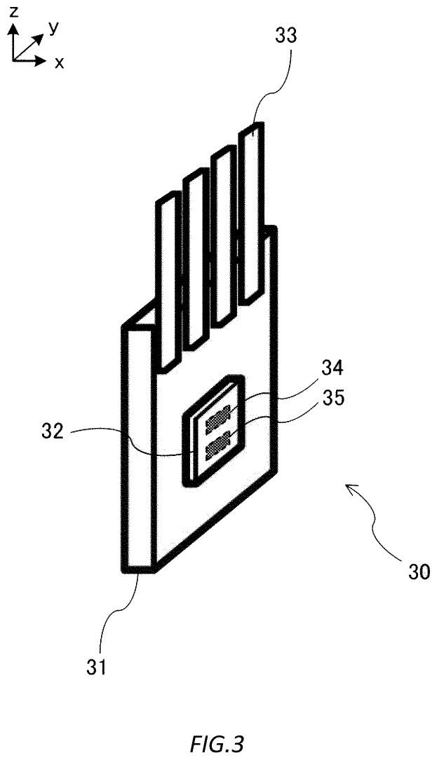

FIG. 3 is a perspective view showing an example of a schematic configuration of the magnetic detection unit 30 in the first embodiment. The magnetic detection unit 30 has a substrate 31, an element portion 32, and a connection terminal 33. For example, two magnetic detection elements 34, 35 are molded with resin to be fixed to the element portion 32. The element portion 32 may be, for example, a magnetic sensor. It should be noted that the number of magnetic detection elements included in the element portion 32 is not limited to two, and for example, the element portion 32 may have only one magnetic detection element, or may have more than two magnetic detection elements. In addition, the number, the arrangement, or the like of the magnetic detection elements is not limited to the form shown in the figure.

When the element portion 32 has the two magnetic detection elements 34, 35, the two magnetic detection elements 34, 35 detect respectively the intensities of magnetic fields that are generated on respective magnetosensitive surfaces by the currents to be measured flowing in the y direction through the two current paths 23, 24, respectively; and output detection signals in accordance with detection intensities detected respectively by the two magnetic detection elements 34, 35. The two magnetic detection elements 34, 35 are respectively arranged such that the magnetic fields that are generated by the currents to be measured flowing in the same direction through the two current paths 23, 24, respectively, pass through the magnetosensitive surfaces for the detection. A plurality of magnetic detection elements may be arranged for the purposes of suppressing a disturbance magnetic field, increasing an output signal, canceling an offset, or the like.

When the element portion 32 is the magnetic sensor, it may include one, or two or more magnetic detection elements, a signal processing IC which processes the output signal based on the detection signal output from the magnetic detection element, an output terminal which outputs the output signal, and a package in which parts of the magnetic detection element, the signal processing IC, and the output terminal are sealed.

As the magnetic detection element, a magnetoelectric conversion element can be used, and as the magnetoelectric conversion elements, for example, a Hall element that is able to obtain the detection signal proportional to a magnitude of a magnetic flux density, can be used. It should be noted that as the magnetoelectric conversion element, a magnetoresistive element, a magnetic impedance element, or the like may be used, in addition to the hall element. Further, as the magnetic detection element, any component with which a detection signal is uniquely determined for a magnetic flux density that is applied, such as a magnetic sensor IC obtained by combining these magnetoelectric conversion elements and an IC processing circuit, can be used. When a plurality of two magnetic detection elements are arranged, shapes and sizes of the magnetic detection elements 34, 35 may be different from each other.

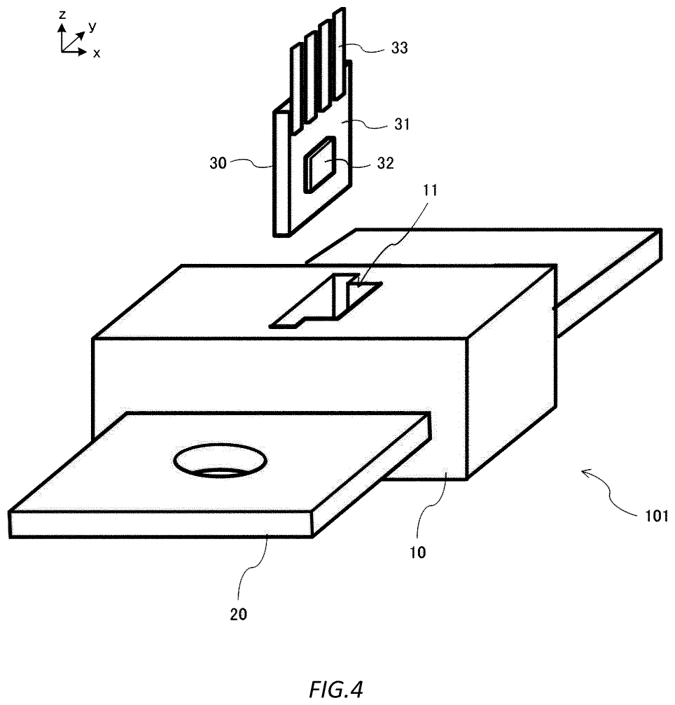

FIG. 4 is an exploded perspective view showing an example of a schematic configuration of the power module 101 in the first embodiment. It should be noted that FIG. 4 depicts only a configuration on a front side (a −y direction side) of the power module 101, and does not depict a configuration on a rear side (a +y direction side), such as the protective resin 40. As shown in FIG. 4, the outer wall resin 10 of the power module 101 has an insertion hole 11 into which the magnetic detection unit 30 is inserted. A surface of the substrate 31 on which the element portion 32 is included, is parallel to an insertion direction (a z direction) of the magnetic detection unit 30.

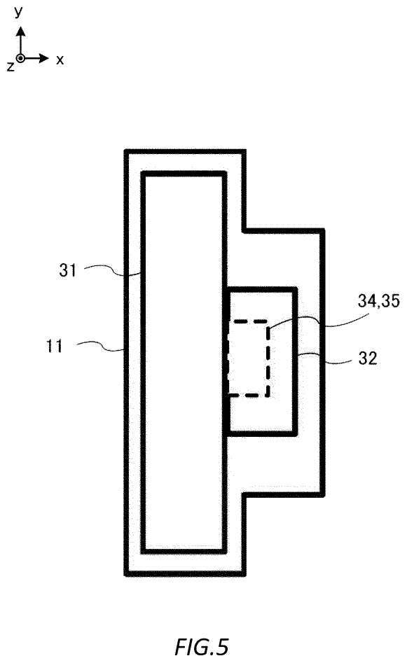

FIG. 5 is a first example of a top plan view showing a schematic configuration of the insertion hole 11 in the first embodiment. FIG. 5 shows a view when seen from the insertion direction (the z direction) of the magnetic detection unit 30. As shown in FIG. 5, when the insertion hole 11 is seen from the insertion direction of the magnetic detection unit 30, the insertion hole 11 has a shape corresponding to an outer shape of the magnetic detection unit 30. The “shape corresponding to an outer shape” of the magnetic detection unit 30 is a shape corresponding to a shape of a projection plane of the magnetic detection unit 30 in the z direction. It can also be said that these are complementary shapes in a direction orthogonal to the insertion direction. For example, when the shape of the projection plane of the magnetic detection unit 30 in the z direction is a right side protruding shape as shown in FIG. 5, the shape of the insertion hole 11 is also a right side protruding shape. Further, the “shape corresponding” means a shape that is slightly larger, rather than the same shape, and in this manner, the magnetic detection unit 30 is able to be inserted into the insertion hole 11.

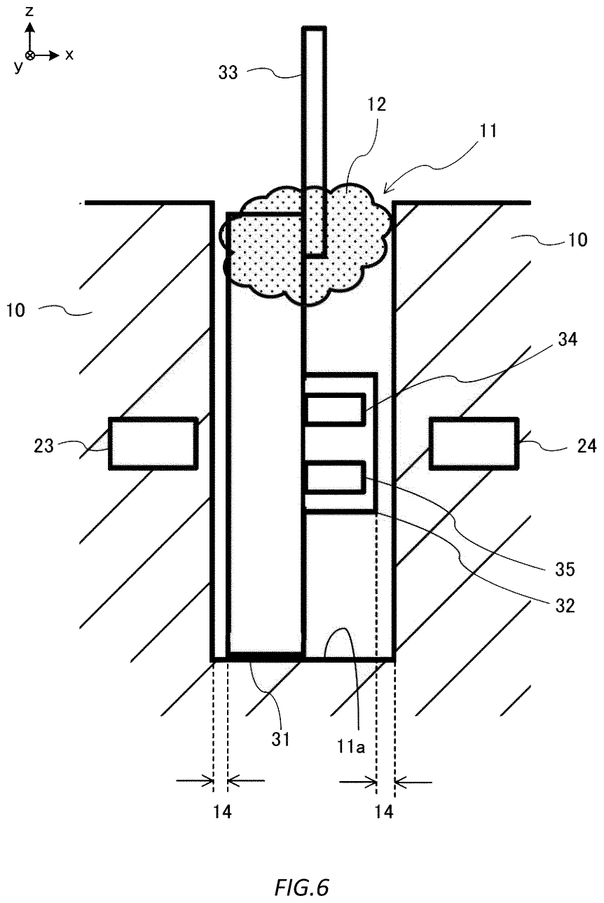

FIG. 6 is a first example of a side cross sectional view showing a schematic configuration of the insertion hole 11 in the first embodiment. In a state in which the magnetic detection unit 30 is inserted into the insertion hole 11, a bottom surface 11a of the outer wall resin 10 which forms the insertion hole 11 is in contact with a lower end portion of the substrate 31 of the magnetic detection unit 30, thereby positioning the magnetic detection unit 30 in a vertical direction. In a state in which the magnetic detection unit 30 is inserted into the insertion hole 11 and is positioned, the magnetic detection unit 30 is fixed to an inside of the insertion hole 11 by an adhesive 12. It should be noted that in a state in which the magnetic detection unit 30 is inserted into the insertion hole 11, the power module 101 has a gap 14 between a side surface of the outer wall resin 10 which forms the insertion hole 11, and a side surface of the magnetic detection unit 30. The current paths 23, 24 of the bus bar 20 are arranged in the outer wall resin 10. That is, a bus bar 20a is not exposed to a front surface of a wall surface of the outer wall resin 10 which forms the insertion hole 11.

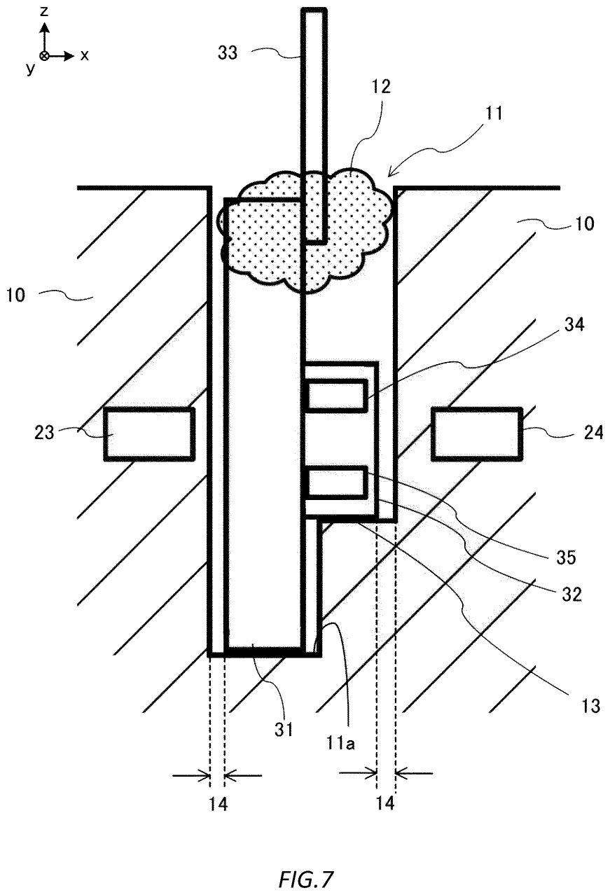

FIG. 7 is a second example of a side cross sectional view showing a schematic configuration of the insertion hole 11 in the first embodiment. A part of the wall surface of the outer wall resin 10 which forms the insertion hole 11 has a positioning portion 13 with which the element portion 32 to which the magnetic detection elements 34, 35 of the magnetic detection unit 30 are fixed, is in contact. The positioning portion 13 is formed based on the shapes of the substrate 31 and the element portion 32, and is a portion of the wall surface of the outer wall resin 10 which forms the insertion hole 11, the portion protruding toward the center of the insertion hole 11 and is in contact with the element portion 32, in a state in which the magnetic detection unit 30 is inserted into the insertion hole 11. That is, the bottom surface 11a of the outer wall resin 10 which forms the insertion hole 11 is in contact with the lower end portion of the substrate 31 of the magnetic detection unit 30, and a lower portion of the element portion 32 is in contact with the positioning portion 13. In this manner, the magnetic detection unit 30 is positioned in the vertical direction. In a state in which the magnetic detection unit 30 is inserted into the insertion hole 11 and is positioned, the magnetic detection unit 30 is fixed to the inside of the insertion hole 11 by the adhesive 12. It should be noted that in a state in which the magnetic detection unit 30 is inserted into the insertion hole 11, the power module 101 has the gap 14 between the side surface of the outer wall resin 10 which forms the insertion hole 11, and the side surface of the magnetic detection unit 30. The current paths 23, 24 of the bus bar 20 are arranged in the outer wall resin 10. That is, the bus bar 20a is not exposed to the front surface of the wall surface of the outer wall resin which forms the insertion hole 11.

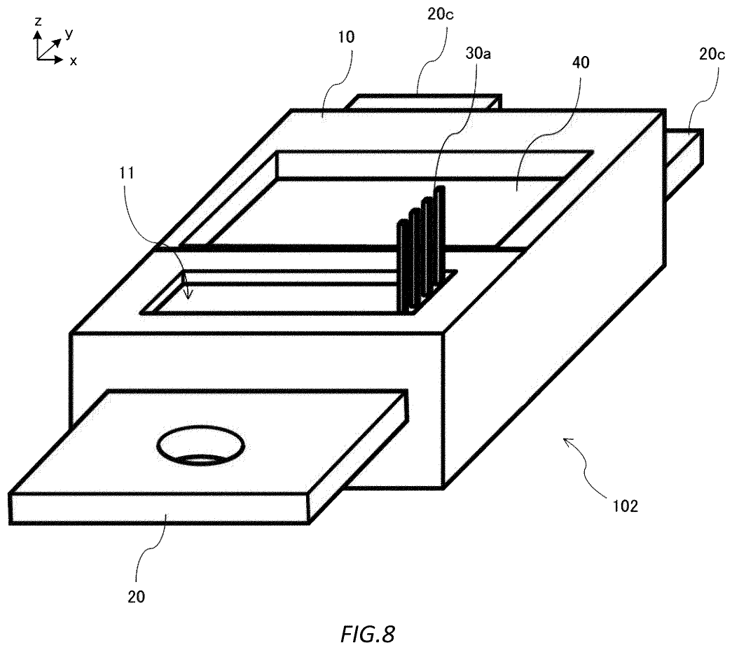

FIG. 8 is a perspective view showing an example of a schematic configuration of a power module 102 in the second embodiment. In the following description, parts common to the power module 101 in the first embodiment are given the same signs and numerals, and the description thereof will be omitted. As shown in FIG. 8, the power module 102 has the outer wall resin 10, the bus bar 20 protruding in the −y direction, a magnetic detection unit 30a, the protective resin 40, and another bus bar 20c protruding in the +y direction. The power module 102 in the second embodiment is a single phase power module.

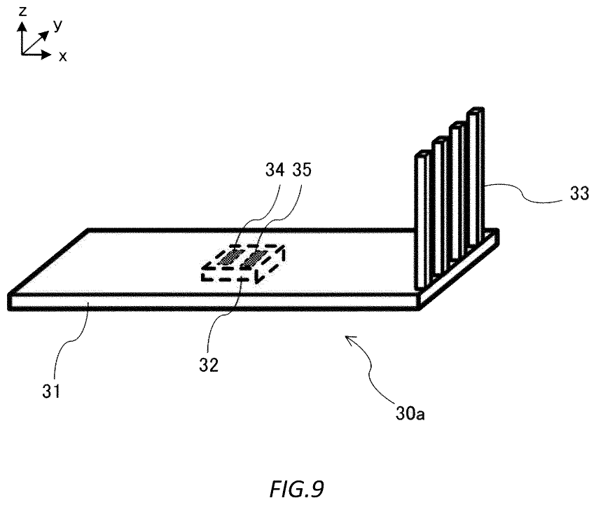

FIG. 9 is a perspective view showing an example of a schematic configuration of the magnetic detection unit 30a in the second embodiment. The magnetic detection unit 30a has the substrate 31, the element portion 32, and the connection terminal 33. For example, two magnetic detection elements 34, 35 are molded with resin to be fixed to the element portion 32. The element portion 32 may be, for example, a magnetic sensor. The magnetic detection unit 30a in the second embodiment is different from the magnetic detection unit 30 in the first embodiment in that the substrate 31 has a surface parallel to the xy plane. The element portion 32 is provided on a lower surface (a surface on a −z direction side) of the substrate 31.

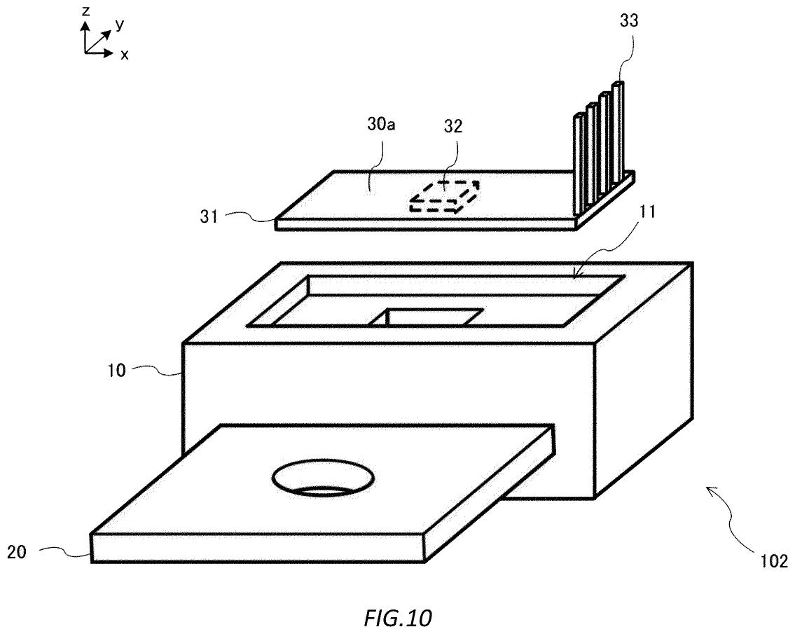

FIG. 10 is an exploded perspective view showing an example of a schematic configuration of the power module 102 in the second embodiment. As shown in FIG. 10, the outer wall resin 10 of the power module 102 has the insertion hole 11 into which the magnetic detection unit 30a is inserted. It should be noted that FIG. 10 depicts only a configuration on a front side (the −y direction side) of the power module 102, and does not depict the protective resin 40 or the like on a rear side (the +y direction side). A surface (the xy plane) of the substrate 31 on which the element portion 32 is included, is orthogonal to the insertion direction (the z direction) of the magnetic detection unit 30a.

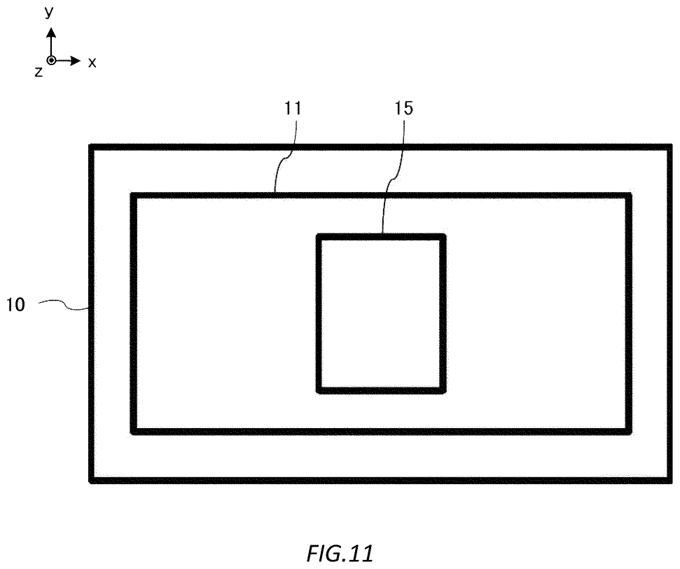

FIG. 11 is a top plan view showing a schematic configuration of the insertion hole 11 in the second embodiment. FIG. 11 shows a view when seen from the insertion direction (the z direction) of the magnetic detection unit 30a. As shown in FIG. 11, when the insertion hole 11 is seen from the insertion direction (the z direction) of the magnetic detection unit 30a, the insertion hole 11 has a shape corresponding to an outer shape of the magnetic detection unit 30a. That is, since the shape of the projection plane of the magnetic detection unit 30a in the z direction is rectangular, the shape of the insertion hole 11 when seen from the z direction is also rectangular. In a center portion of the insertion hole 11, a recess 15 in which the element portion 32 protruding in the −z direction is arranged, is provided.

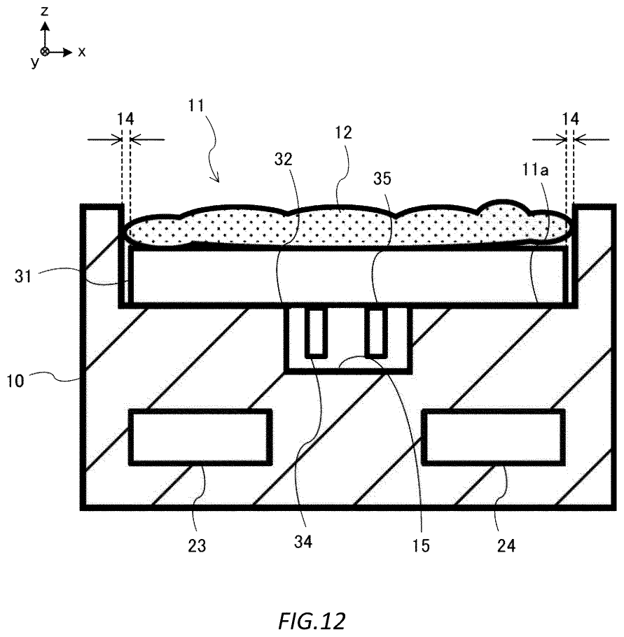

FIG. 12 is a side cross sectional view showing a schematic configuration of the insertion hole 11 in the second embodiment. As shown in FIG. 12, the outer shape of the magnetic detection unit 30a is a downwardly protruding shape when seen from the y direction as shown in FIG. 12, and thus the shape of the insertion hole 11 is a downwardly protruding shape. In a state in which the magnetic detection unit 30a is inserted into the insertion hole 11, a part of the wall surface of the outer wall resin 10 which forms the insertion hole 11 is in contact with the lower end portion of the substrate 31 of the magnetic detection unit 30a. In this manner, the magnetic detection unit 30a is positioned in the vertical direction. In a state in which the magnetic detection unit 30a is inserted into the insertion hole 11 and is positioned, the magnetic detection unit 30a is fixed to the inside of the insertion hole 11 by the adhesive 12. It should be noted that the magnetic detection unit 30a is inserted into the insertion hole 11, and the power module 102 has the gap 14 between the side surface of the outer wall resin 10 which forms the insertion hole 11, and the side surface of the substrate 31 of the magnetic detection unit 30a. In addition, the current paths 23, 24 of the bus bar 20 are arranged in the outer wall resin 10. The lower surface of the element portion 32 may be in contact with the wall surface of the outer wall resin 10 which forms the recess 15, or a gap may be included between the element portion 32, and the wall surface of the outer wall resin 10 which forms the recess 15.

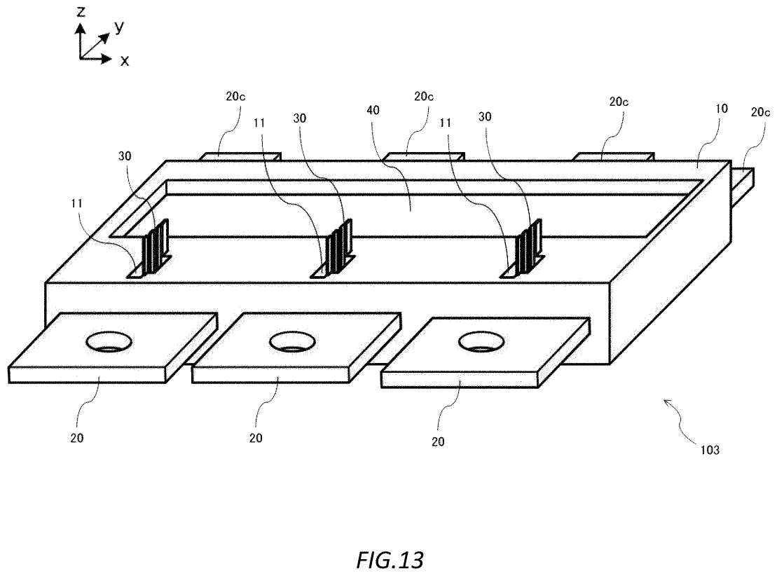

FIG. 13 is a perspective view showing an example of a schematic configuration of a power module 103 in the third embodiment. In the following description, parts common to the power module 101 in the first embodiment are given the same signs and numerals, and the description thereof will be omitted. The power module 103 in the third embodiment is a power module for a three phase motor, and includes three bus bars 20, and the three bus bars 20 are arranged side by side in an x direction.

The three bus bars 20 correspond to a U phase, a V phase, and a W phase of a three phase alternating current, respectively.

As shown in FIG. 13, the power module 103 has the outer wall resin 10, three bus bars 20 protruding in the −y direction, three magnetic detection units 30, the protective resin 40, and another bus bar 20c protruding in the +y direction. Each of the three magnetic detection units 30 is the same as the magnetic detection unit 30 shown in FIG. 3, and each of the three bus bars 20 is the same as the bus bar 20 shown in FIG. 2. The outer wall resin 10 of the power module 103 has three insertion holes 11 into which the three magnetic detection units 30 are inserted. When seen from the insertion directions of the three magnetic detection units 30, the three insertion holes 11 have shapes corresponding to outer shapes of the three magnetic detection units 30. The shapes of the three insertion holes 11 are the same as the shapes shown in FIG. 5 and FIG. 6.

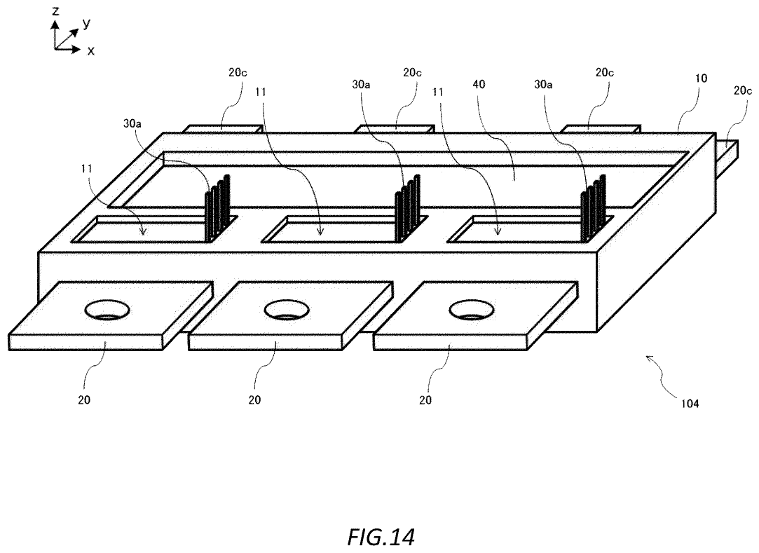

FIG. 14 is a perspective view showing an example of a schematic configuration of a power module 104 in the fourth embodiment. In the following description, parts common to the power module 101 in the first embodiment are given the same signs and numerals, and the description thereof will be omitted. The power module 104 in the fourth embodiment is a power module for a three phase motor, and includes three bus bars 20 in the first embodiment, and the three bus bars 20 are arranged side by side in the x direction.

The three bus bars 20 correspond to a U phase, a V phase, and a W phase of a three phase alternating current, respectively.

As shown in FIG. 14, the power module 104 has the outer wall resin 10, three bus bars 20 protruding in the −y direction, three magnetic detection units 30a, the protective resin 40, and another bus bar 20c protruding in the +y direction. Each of the three magnetic detection units 30a is the same as the magnetic detection unit 30a shown in FIG. 9. The outer wall resin 10 of the power module 104 has three insertion holes 11 into which the three magnetic detection units 30a are inserted. When seen from the insertion directions of the three magnetic detection units 30a, the three insertion holes 11 have shapes corresponding to outer shapes of the three magnetic detection units 30a. The shapes of the three insertion holes 11 are the same as the shapes shown in FIG. 10 and FIG. 11.

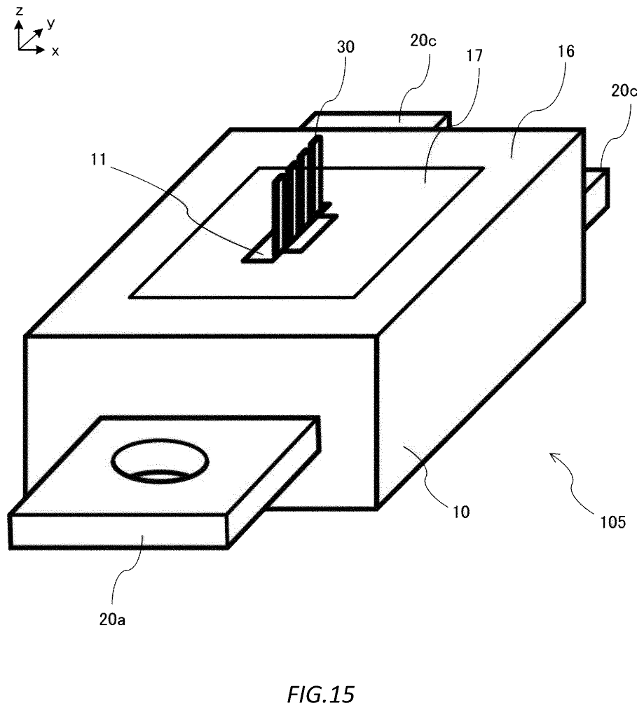

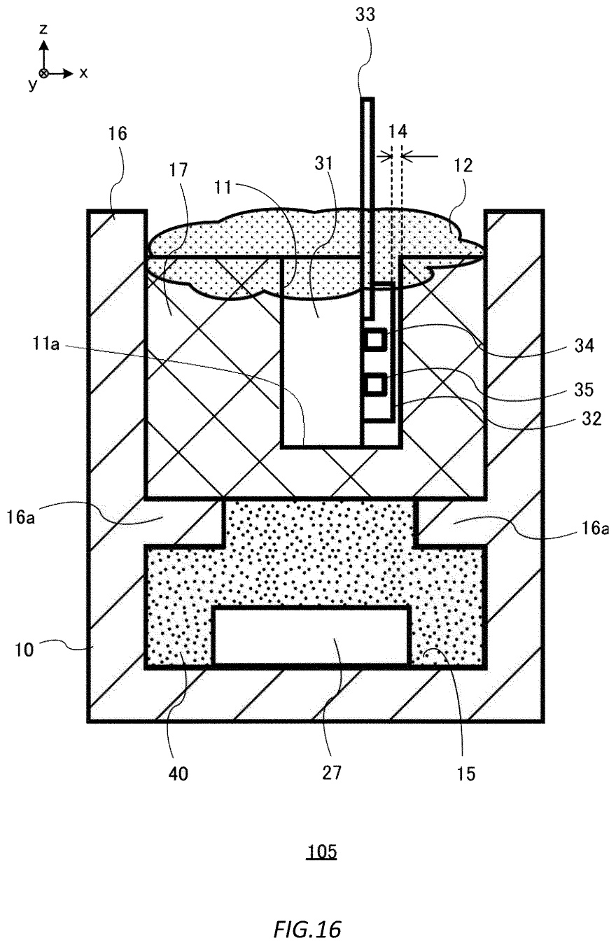

FIG. 15 is a perspective view showing an example of a schematic configuration of a power module 105 in a fifth embodiment. In the following description, parts common to the power module 101 in the first embodiment are given the same signs and numerals, and the description thereof will be omitted. As shown in FIG. 15, the power module 105 has the outer wall resin 10, the bus bar 20a protruding in the −y direction, a current path 27 which is connected to the bus bar 20a, the magnetic detection unit 30, the protective resin 40, and another bus bar 20c protruding in the +y direction. The current path 27 is connected to the bus bar 20a by screwing, welding, or a method other than that. The power module 105 in the fifth embodiment is a single phase power module. The magnetic detection unit 30 is the same as the magnetic detection unit 30 shown in FIG. 3, and the insertion hole 11 into which the magnetic detection unit 30 is inserted is the same as the insertion hole 11 shown in FIG. 4 and FIG. 5. The protective resin 40 is arranged inside the power module 105, and thus will be described with reference to FIG. 16.

FIG. 16 is a side cross sectional view showing a schematic configuration of the power module 105 in the fifth embodiment. As shown in FIG. 16, the outer wall resin 10 has a first portion 16 which surrounds at least parts of the current path 23 and the protective resin 40, and a second portion 17 in which the insertion hole 11 is provided. The first portion 16 has a protruding portion 16a which supports the second portion 17 from below. In this example, the first portion 16 and the second portion 17 are formed separately. The second portion 17 is provided with the insertion hole 11, into which the magnetic detection unit 30 is inserted. In a state in which the magnetic detection unit 30 is inserted into the insertion hole 11, the bottom surface 11a of the outer wall resin 10 which forms the insertion hole 11 is in contact with the lower end portion of the substrate 31 of the magnetic detection unit 30, for the positioning. In a state in which the magnetic detection unit 30 is inserted into the insertion hole 11 and is positioned, the magnetic detection unit 30 is fixed to the inside of the insertion hole 11 by the adhesive 12. It should be noted that in a state in which the magnetic detection unit 30 is inserted into the insertion hole 11, the power module 105 has the gap 14 between the side surface of the outer wall resin 10 which forms the insertion hole 11, and the side surface of the magnetic detection unit 30. A part of the bus bar 20a, and the current path 27 which is connected to the bus bar 20a are covered with the protective resin 40.

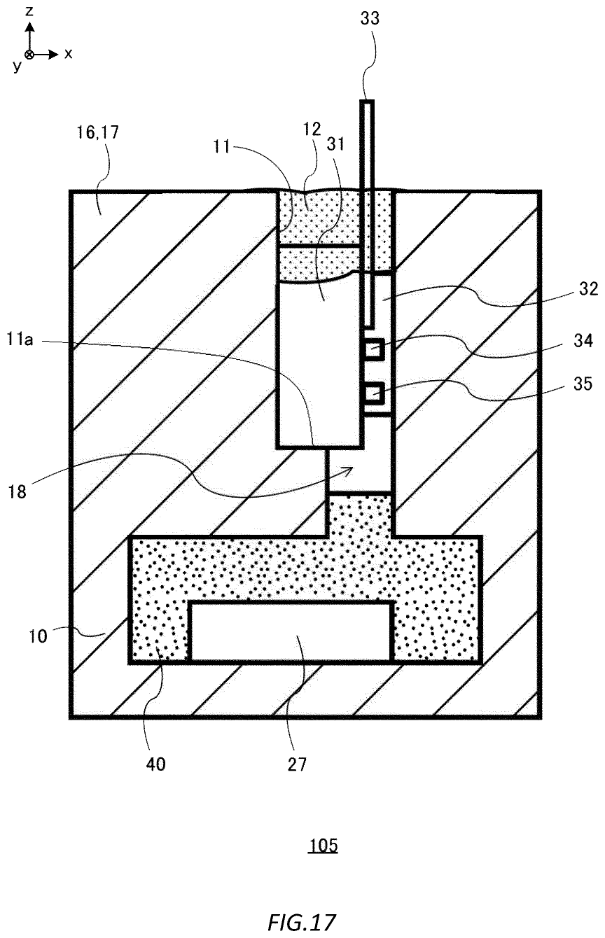

FIG. 17 is another example of the side cross sectional view showing a schematic configuration of the power module 105 in the fifth embodiment. As shown in FIG. 17, the outer wall resin 10 has the first portion 16 which surrounds at least a part of the current path 27, and the second portion 17 in which the insertion hole 11 is provided. In another example, the first portion 16 and the second portion 17 are integrally molded. Accordingly, in FIG. 17, the first portion 16 and the second portion 17 are indicated by the same hatching. The second portion 17 which forms a lid is provided with the insertion hole 11, into which the magnetic detection unit 30 is inserted. In a state in which the magnetic detection unit 30 is inserted into the insertion hole 11, the bottom surface 11a of the outer wall resin 10 which forms the insertion hole 11 is in contact with the lower surface of the substrate 31 of the magnetic detection unit 30, for the positioning. In a state in which the magnetic detection unit 30 is inserted into the insertion hole 11 and is positioned, the magnetic detection unit 30 is fixed to the inside of the insertion hole 11 by the adhesive 12. An injection hole 18 for injecting the protective resin 40 is provided above the current path 27 which is connected to the bus bar 20a, and the current path 27 is covered with the protective resin 40.

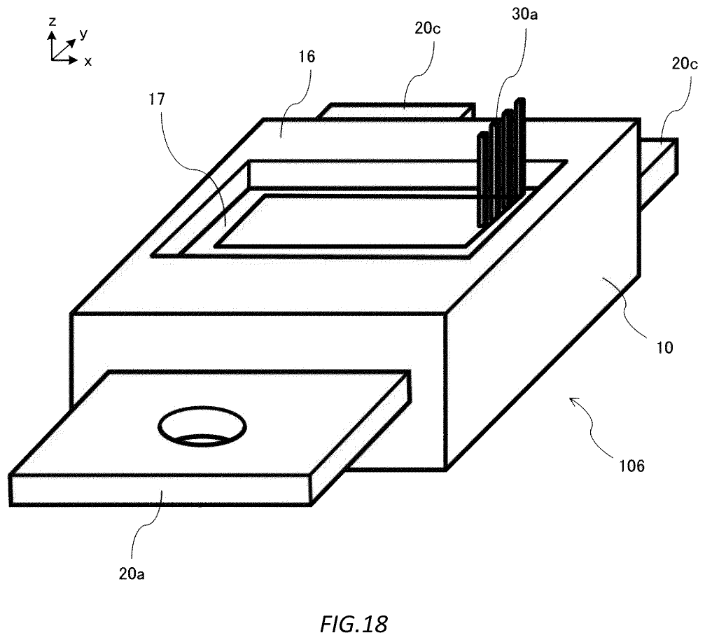

FIG. 18 is a perspective view showing an example of a schematic configuration of a power module 106 in a sixth embodiment. In the following description, parts common to the power module 101 in the first embodiment are given the same signs and numerals, and the description thereof will be omitted. As shown in FIG. 18, the power module 106 has the outer wall resin 10, the bus bar 20a protruding in the −y direction, the current path 27 which is connected to the bus bar 20a, the magnetic detection unit 30a, and another bus bar 20c protruding in the +y direction. The power module 106 in the sixth embodiment is a single phase power module. The magnetic detection unit 30a is the same as the magnetic detection unit 30a shown in FIG. 9. The bus bar 20a in the present embodiment is the same as the bus bar 20a in the fifth embodiment.

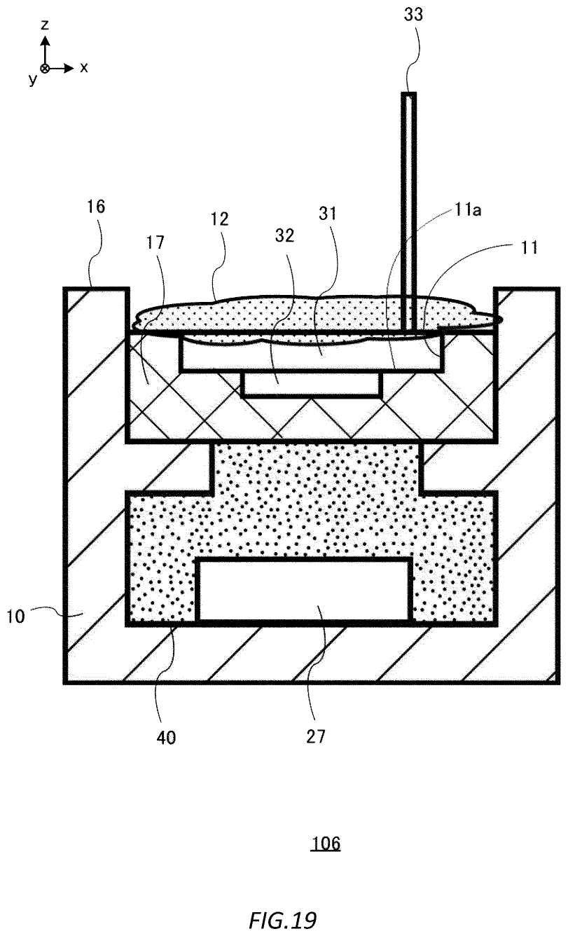

FIG. 19 is a side cross sectional view showing a schematic configuration of the power module 106 in the sixth embodiment. As shown in FIG. 19, the outer wall resin 10 has the first portion 16 which surrounds at least parts of the current path 27 and the protective resin 40, and the second portion 17 in which the insertion hole 11 is provided. In this example, the first portion 16 and the second portion 17 are formed separately. The second portion 17 is provided with the insertion hole 11, into which the magnetic detection unit 30a is inserted. In a state in which the magnetic detection unit 30a is inserted into the insertion hole 11, the bottom surface 11a of the outer wall resin 10 which forms the insertion hole 11 is in contact with the substrate 31 of the magnetic detection unit 30a, for the positioning. In a state in which the magnetic detection unit 30a is inserted into the insertion hole 11 and is positioned, the magnetic detection unit 30a is fixed to the inside of the insertion hole 11 by the adhesive 12. A part of the bus bar 20a, and the current path 27 which is connected to the bus bar 20a are covered with the protective resin 40.

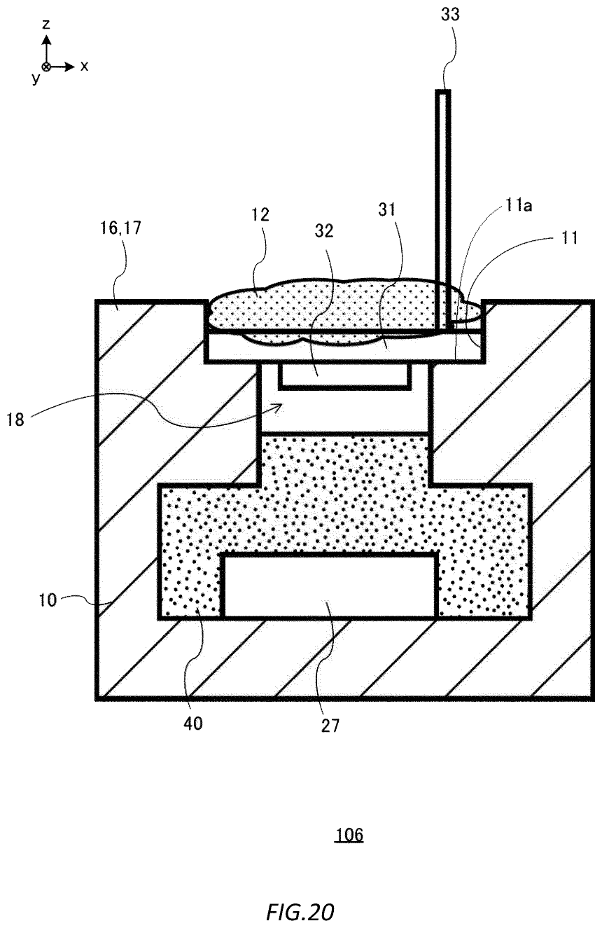

FIG. 20 is another example of the side cross sectional view showing a schematic configuration of the power module 106 in the sixth embodiment. As shown in FIG. 20, the outer wall resin 10 has the first portion 16 which surrounds at least parts of the current path 23 and the protective resin 40, and the second portion 17 in which the insertion hole 11 is provided. In another example, the first portion 16 and the second portion 17 are integrally molded. Accordingly, in FIG. 20, the first portion 16 and the second portion 17 are indicated by the same hatching. The second portion 17 which forms a lid is provided with the insertion hole 11, into which the magnetic detection unit 30a is inserted. In a state in which the magnetic detection unit 30a is inserted into the insertion hole 11, the bottom surface 11a of the outer wall resin 10 which forms the insertion hole 11 is in contact with the substrate 31 of the magnetic detection unit 30a, for the positioning. In a state in which the magnetic detection unit 30a is inserted into the insertion hole 11 and is positioned, the magnetic detection unit 30 is fixed to the inside of the insertion hole 11 by the adhesive 12. An injection hole 18 for injecting the protective resin 40 is provided above the current path 27 which is connected to the bus bar 20a, and the current path 27 is covered with the protective resin 40.

In the fifth and sixth embodiments, when the element portion 32 has two magnetoelectric conversion elements 34, 35, the magnetoelectric conversion elements 34, 35 respectively detect the intensities of the magnetic fields that are generated on respective magnetosensitive surfaces by the currents to be measured flowing through the current path 27, respectively; and output detection signals in accordance with detection intensities detected respectively by the two magnetic detection elements 34, 35. In this case, the shape of the bus bar 20a may be, as an example, a rectangular shape consisting of only the main body portion.

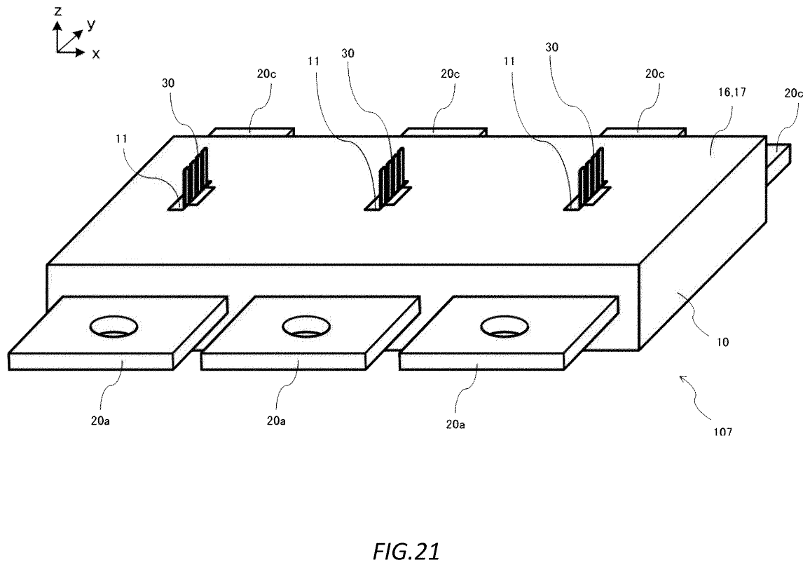

FIG. 21 is a perspective view showing an example of a schematic configuration of a power module 107 in a seventh embodiment. In the following description, parts common to the power module 101 in the first embodiment are given the same signs and numerals, and the description thereof will be omitted. The power module 107 in the seventh embodiment is a power module for a three phase motor. As shown in FIG. 21, the power module 107 has the outer wall resin 10, three bus bars 20a protruding in the −y direction, three magnetic detection units 30, and another bus bar 20c protruding in the +y direction. The three bus bars 20a are arranged side by side in the x direction. The three bus bars 20a are the same as the bus bars 20a shown in FIG. 17 in the fifth and sixth embodiments, and the three magnetic detection units 30 are the same as the magnetic detection unit 30 shown in FIG. 3.

The three bus bars 20a correspond to a U phase, a V phase, and a W phase of a three phase alternating current, respectively.

The outer wall resin 10 has the first portion 16 which surrounds at least parts of the current path 27 and the protective resin 40, and the second portion 17 in which the insertion hole 11 is provided. The first portion 16 and the second portion 17 are integrally molded. Accordingly, in FIG. 21, the first portion 16 and the second portion 17 are indicated by the same hatching. The second portion 17 is provided with the insertion hole 11, into which the magnetic detection unit 30 is inserted. The outer wall resin 10 of the power module 107 has three insertion holes 11 into which the three magnetic detection units 30 are inserted. When seen from the insertion directions of the three magnetic detection units 30, the three insertion holes 11 have shapes corresponding to outer shapes of the three magnetic detection units 30. The shapes of the three insertion holes 11 are the same as the shapes shown in FIG. 4 and FIG. 5.

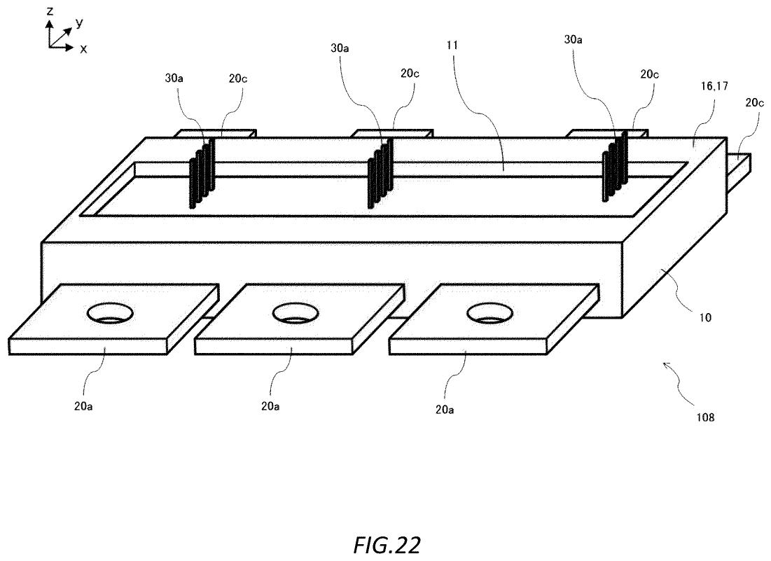

FIG. 22 is a perspective view showing an example of a schematic configuration of a power module 108 in an eighth embodiment. In the following description, parts common to the power module 101 in the first embodiment are given the same signs and numerals, and the description thereof will be omitted. The power module 108 in the eighth embodiment is a power module for a three phase motor. As shown in FIG. 22, the power module 108 has the outer wall resin 10, three bus bars 20a protruding in the −y direction, three magnetic detection units 30a, and another bus bar 20c protruding in the +y direction. The three bus bars 20a are arranged side by side in the x direction. Each of the three magnetic detection units 30a is the same as the magnetic detection unit 30a shown in FIG. 9. Each of the three bus bars 20a is the same as the bus bar 20a shown in FIG. 17.

The three bus bars 20a correspond to a U phase, a V phase, and a W phase of a three phase alternating current, respectively.

The outer wall resin 10 has the first portion 16 which surrounds at least parts of the current path 27 and the protective resin 40, and the second portion 17 in which the insertion hole 11 is provided. In another example, the first portion 16 and the second portion 17 are integrally molded. Accordingly, in FIG. 22, the first portion 16 and the second portion 17 are indicated by the same hatching. The second portion 17 is provided with the insertion hole 11, into which the three magnetic detection units 30a are inserted. When seen from the insertion directions of the three magnetic detection units 30a, the insertion hole 11 has a shape corresponding to the outer shapes of the three magnetic detection units 30a. A cross sectional view in the vicinity of each bus bar 20a is the same as the cross sectional view shown in FIG. 19.

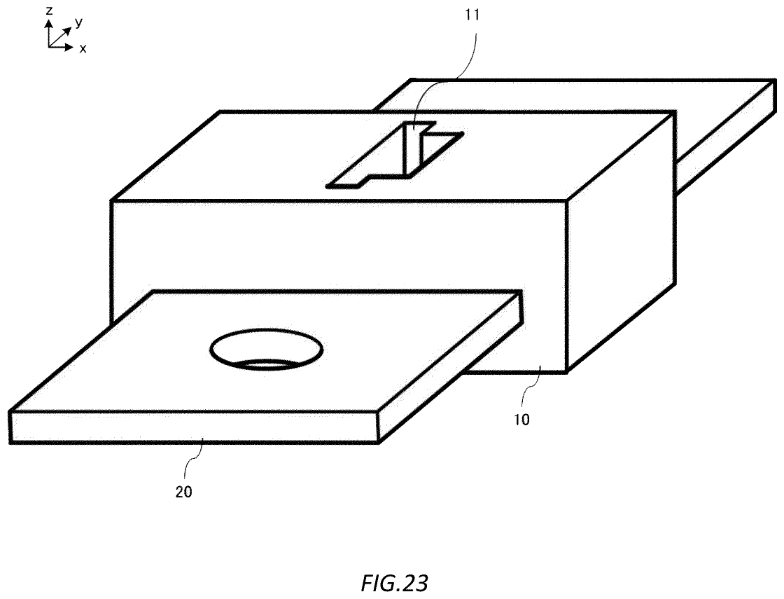

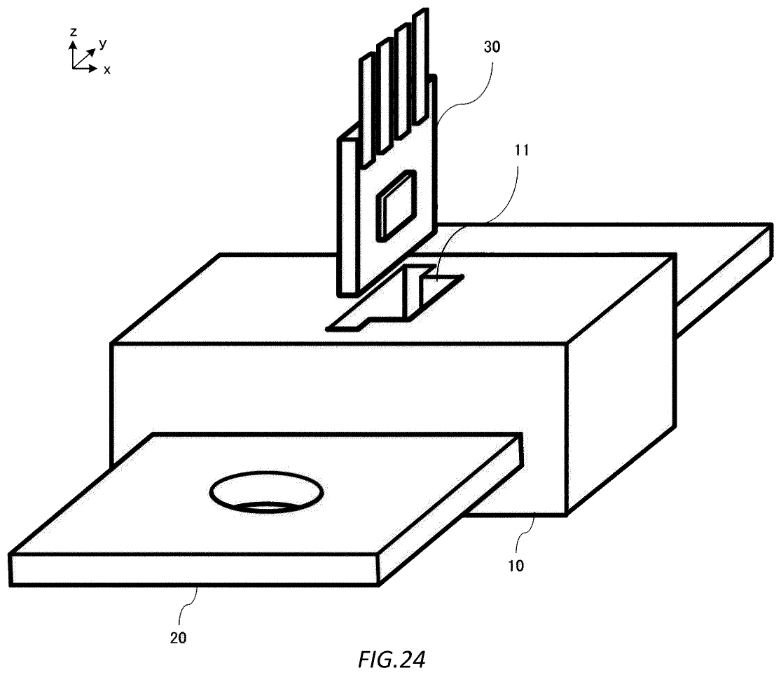

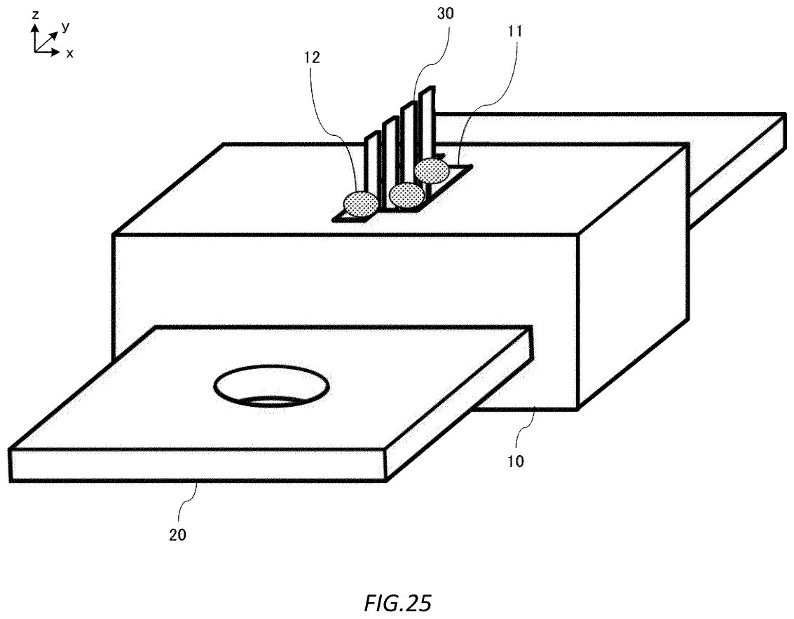

FIG. 23 to FIG. 25 are illustrations showing parts of a process of manufacturing the power module 101 in the first embodiment. It should be noted that FIG. 23 to FIG. 25 depict only a configuration on the front side (the −y direction side) of the power module 101, and does not depict the protective resin 40 or the like on the rear side (the +y direction side). In the first step, the bus bar 20 shown in FIG. 2 is prepared. In the second step, as shown in FIG. 23, resin molding is performed on the vicinity of the bus bar 20 to form the outer wall resin 10 having the insertion hole 11 into which the magnetic detection unit 30 is inserted. In the third step, as shown in FIG. 24, the magnetic detection unit 30 is inserted into the insertion hole 11 from a +z direction. In the fourth step, as shown in FIG. 25, the adhesive 12 is applied to the gap of insertion hole 11 to fix the magnetic detection unit 30.

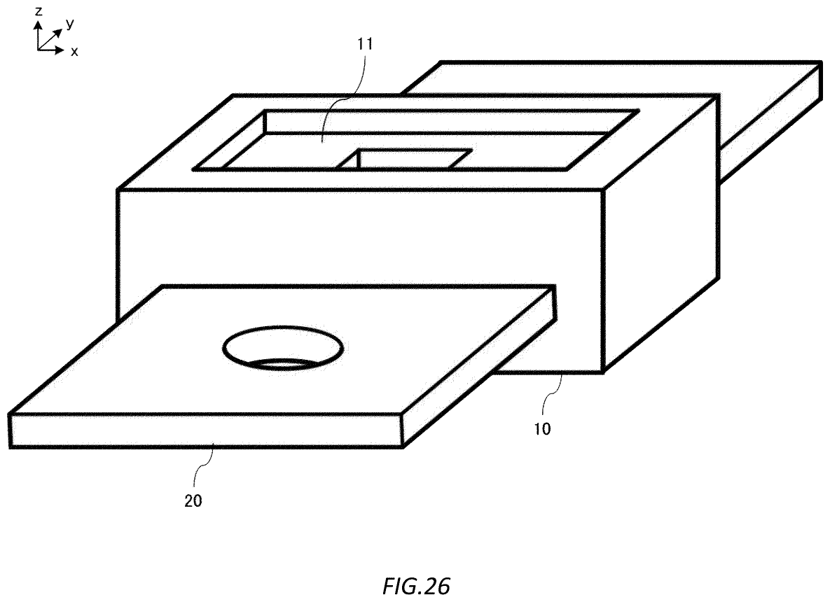

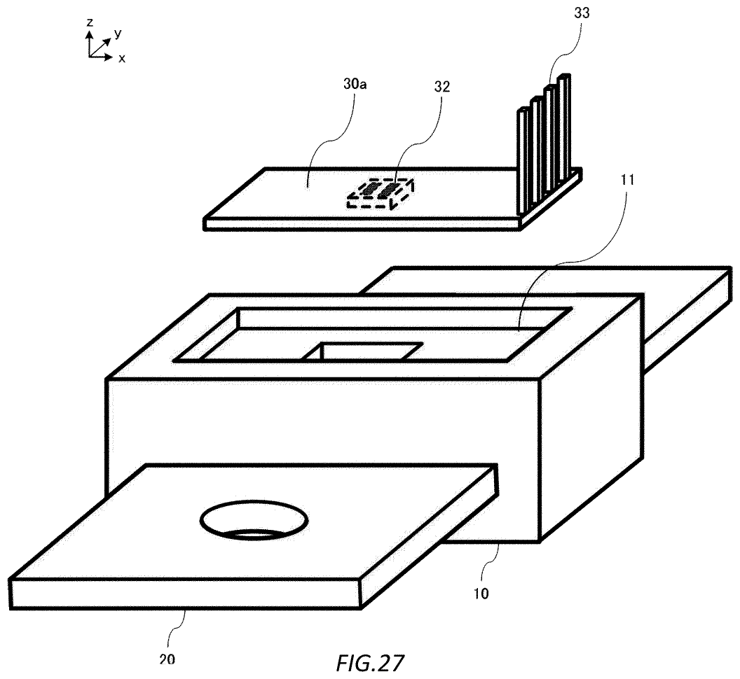

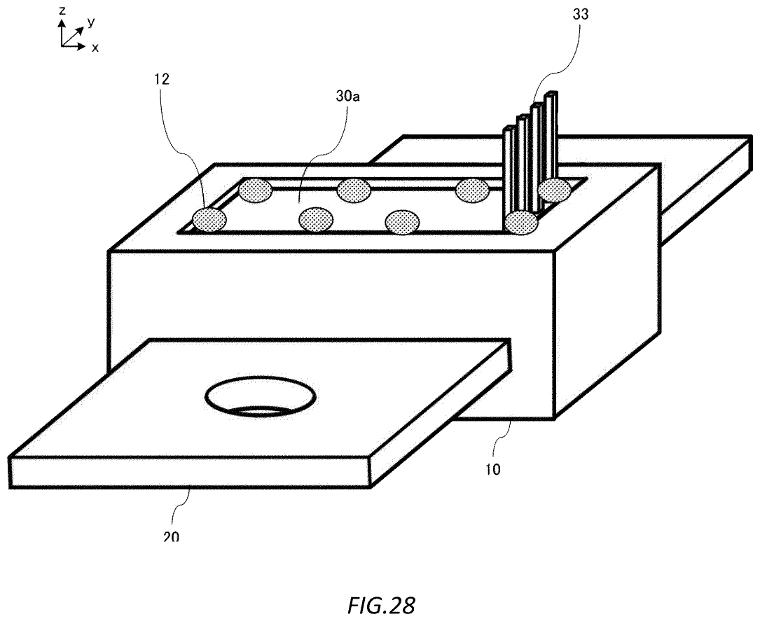

FIG. 26 to FIG. 28 are illustrations showing parts of a process of manufacturing the power module 102 in the second embodiment. It should be noted that FIG. 26 to FIG. 28 depict only a configuration on the front side (the −y direction side) of the power module 102, and does not depict the protective resin 40 or the like on a rear side (the +y direction side). In the first step, the bus bar 20 shown in FIG. 2 is prepared. In the second step, as shown in FIG. 26, resin molding is performed on the vicinity of the bus bar 20 to form the outer wall resin 10 having the insertion hole 11 into which the magnetic detection unit 30a is inserted. In the third step, as shown in FIG. 27, the magnetic detection unit 30a is inserted into the insertion hole 11 from the +z direction. In the fourth step, as shown in FIG. 28, the adhesive 12 is applied to the gap of insertion hole 11 to fix the magnetic detection unit 30a.

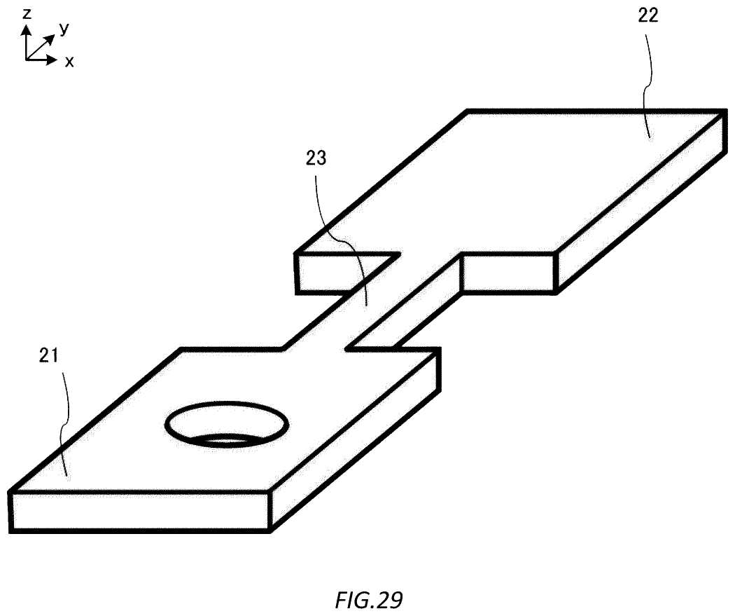

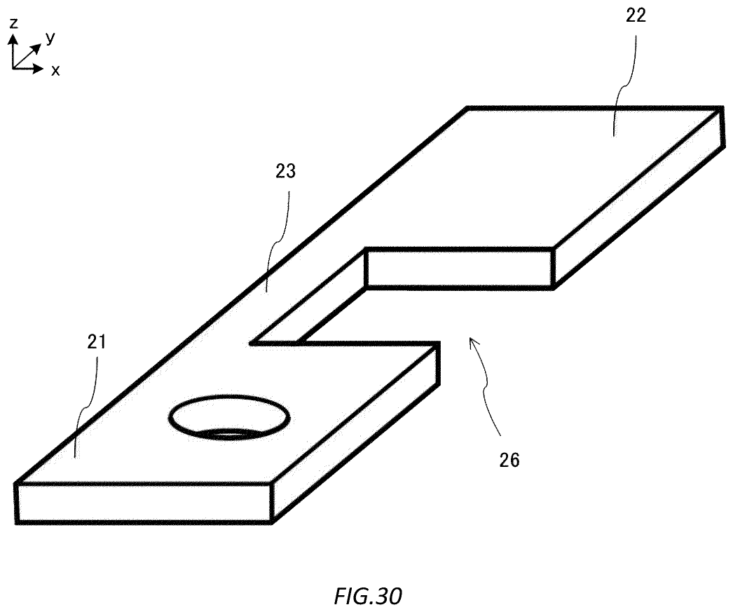

FIG. 29 and FIG. 30 are perspective views showing examples of a schematic configuration of a modified example of the bus bar 20 which is used in the first embodiment to the fourth embodiment. The bus bar shown in FIG. 29 has two main body portions 21, 22 and one current path 23, and as shown in FIG. 16, the two main body portions 21, 22 are arranged side by side in the y direction. The current path 23 is arranged between the two main body portions 21, 22, and connects the two main body portions 21, 22. The current to be measured flows in the y direction through the current path 23. The bus bar shown in FIG. 30 has two main body portions 21, 22, one current path 23, and a cutout 26. The bus bar in FIG. 30 is bilaterally asymmetric.

As described above, according to the first to eleventh embodiments, the outer wall resin 10 has the insertion hole 11, and when seen from the insertion directions of the magnetic detection unit 30, 30a, the insertion hole 11 has a shape corresponding to the outer shapes of the magnetic detection unit 30, 30a. This makes it possible for the magnetic detection units 30, 30a to be inserted into the outer wall resin 10 and easily fixed, and also makes it possible to prevent the magnetic detection units 30, 30a from shifting in position.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: outer wall resin; 11: insertion hole; 11a: bottom surface; 12: adhesive; 13: positioning portion; 14: gap; 15: recess; 16: first portion; 17: second portion; 18: injection hole; 20: bus bar; 20a: bus bar; 20c: another bus bar; 21: main body portion; 22: main body portion; 23: current path; 24: current path; 25: through hole; 26: cutout; 27: current path; 30: magnetic detection unit; 30a: magnetic detection unit; 31: substrate; 32: element portion; 33: connection terminal; 34: magnetic detection element; 35: magnetic detection element; 40: protective resin; 101 to 108: power module.

What is claimed is:

1. A power module comprising:
a bus bar, a magnetic detection unit, and outer wall resin, wherein
the magnetic detection unit has a magnetic detection element, an element portion to which the magnetic detection element is fixed, and a substrate to which the element portion is fixed,
the outer wall resin has an insertion hole into which the magnetic detection unit is inserted,
when seen from an insertion direction of the magnetic detection unit, the insertion hole has a shape corresponding to an outer shape of the magnetic detection unit, and
the outer wall resin has a positioning portion with which the element portion of the magnetic detection unit is in contact, on a part of a wall surface which forms the insertion hole.

2. The power module according to claim 1, wherein
the magnetic detection unit has a magnetic detection element, and a substrate to which the magnetic detection element is fixed, and
a surface of the substrate on which the magnetic detection element is included, is orthogonal to the insertion direction.

3. The power module according to claim 1, wherein
the magnetic detection unit has a magnetic detection element, and a substrate to which the magnetic detection element is fixed, and
a surface of the substrate on which the magnetic detection element is included, is parallel to the insertion direction.

4. The power module according to claim 1, wherein the outer wall resin covers a part of the bus bar.

5. The power module according to claim 2, wherein the outer wall resin covers a part of the bus bar.

6. The power module according to claim 3, wherein the outer wall resin covers a part of the bus bar

7. The power module according to claim 1, wherein three bus bars, each of which is the bus bar, are arranged side by side in a direction orthogonal to an extension direction of the bus bar.

8. The power module according to claim 2, wherein three bus bars, each of which is the bus bar, are arranged side by side in a direction orthogonal to an extension direction of the bus bar.

9. The power module according to claim 3, wherein three bus bars, each of which is the bus bar, are arranged side by side in a direction orthogonal to an extension direction of the bus bar.

10. The power module according to claim 4, wherein three bus bars, each of which is the bus bar, are arranged side by side in a direction orthogonal to an extension direction of the bus bar.

11. The power module according to claim 1, comprising only one bus bar, which is the bus bar.

12. The power module according to claim 1, wherein the magnetic detection unit is inserted into the insertion hole, and a gap is included between a wall surface of the outer wall resin which forms the insertion hole, and a side surface of the magnetic detection unit.

13. The power module according to claim 1, wherein in a state in which a gap is included between a wall surface of the outer wall resin which forms the insertion hole, and a side surface of the magnetic detection unit, the magnetic detection unit is fixed to an inside of the insertion hole.

14. The power module according to claim 1, wherein the magnetic detection unit is inserted into the insertion hole, and a lower surface of a wall surface of the outer wall resin which forms the insertion hole is in contact with a lower end portion of the magnetic detection unit.

15. The power module according to claim 1, wherein
the magnetic detection unit has a magnetic detection element, and a substrate to which the magnetic detection element is fixed, and
the magnetic detection unit is inserted into the insertion hole, and a part of a wall surface of the outer wall resin which forms the insertion hole is in contact with a lower surface of the substrate.

16. The power module according to claim 1, wherein the outer wall resin has a first portion which surrounds at least a part of the bus bar, and a second portion in which the insertion hole is provided.

17. The power module according to claim 1, wherein the bus bar is not exposed to the insertion hole.

18. The power module according to claim 1, wherein the insertion hole has a shape complementary to the outer shape of the magnetic detection unit in a surface orthogonal to the insertion direction.

19. Outer wall resin for a power module which has a bus bar and a magnetic detection unit, the magnetic detection unit including a magnetic detection element, an element portion to which the magnetic detection element is fixed, and a substrate to which the element portion is fixed,
the outer wall resin for a power module comprising:
an insertion hole into which the magnetic detection unit is inserted; and
a positioning portion with which the element portion of the magnetic detection unit is in contact, on a part of a wall surface which forms the insertion hole, wherein
when seen from an insertion direction of the magnetic detection unit, the insertion hole has a shape corresponding to an outer shape of the magnetic detection unit.

20. A method of manufacturing a power module which has a bus bar and a magnetic detection unit, the magnetic detection unit including a magnetic detection element, an element portion to which the magnetic detection element is fixed, and a substrate to which the element portion is fixed,
the method of manufacturing a power module comprising:
performing resin molding on the bus bar, and forming outer wall resin having an insertion hole into which the magnetic detection unit is inserted, and a positioning portion with which the element portion of the magnetic detection unit is caused to be in contact, on a part of a wall surface which forms the insertion hole; and
inserting the magnetic detection unit into the insertion hole, and causing the element portion of the magnetic detection unit to be in contact with the positioning portion, wherein
when seen from an insertion direction in which the magnetic detection unit is inserted into the outer wall resin, the insertion hole has a shape corresponding to an outer shape of the magnetic detection unit.
